(19) United States
(12) Patent Application Publication
(10) Pub. No.: US 2018/0286973 A1
(43) Pub. Date: Oct. 4, 2018

(54) HIGH FREQUENCY DEVICE

(71) Applicants: Kabushiki Kaisha Toshiba, Minato-ku (JP); Toshiba Infrastructure Systems & Solutions Corporation, Saiwai-ku (JP)

(72) Inventor: Kenichi SUGITA, Kawasaki (JP)

(73) Assignees: Kabushiki Kaisha Toshiba, Minato-ku (JP); Toshiba Infrastructure Systems & Solutions Corporation, Saiwai-ku (JP)

(21) Appl. No.: 15/873,102

(22) Filed: Jan. 17, 2018

(30) Foreign Application Priority Data
Mar. 30, 2017 (JP) 2017-068192

(51) Int. Cl. H01L 29/778; H01L 29/205; H01L 29/20; H01L 23/66; H01L 29/66

(52) U.S. Cl. CPC H01L 29/7787; H01L 29/205; H01L 21/02381; H01L 23/66; H01L 29/66462; H01L 29/2003

(57) ABSTRACT

A high frequency device includes a first nitride semiconductor layer; a second nitride semiconductor layer provided on the first nitride semiconductor layer, and a third nitride semiconductor layer provided on the second nitride semiconductor layer. The second nitride semiconductor layer includes indium atoms, and has a layer thickness in a range of not less than 0.26 nanometers and not more than 100 nanometers.

### CROSS-REFERENCE TO RELATED APPLICATIONS

This application is based upon and claims the benefit of priority from Japanese Patent Application No. 2017-068192, filed on Mar. 30, 2017; the entire contents of which are incorporated herein by reference.

### FIELD

Embodiments generally relate to a high frequency device.

### BACKGROUND

There has been a high frequency device such as a high electron mobility transistor (HEMT), which has a structure including an InGaN layer of nitride semiconductor thickly formed between nitride semiconductor layers of a GaN layer and an AlGaN layer.

When the InGaN layer is formed thick, however, the lattice coupling between the GaN layer and the InGaN layer is broken, and lattice relaxation takes place in the InGaN layer. The lattice relaxation in the InGaN layer causes disorders in the crystal structure, resulting in crystal defects and like which scatter the carrier electrons. Thus, there may be drawbacks such as reductions of electron mobility and electron density in two-dimensional electron gas (2DEG) induced at the interface between the InGaN layer and the AlGaN layer.

### BRIEF DESCRIPTION OF THE DRAWINGS

FIGS. 1A and 1B are cross-sectional views of a high frequency device according to an embodiment;

FIG. 2 is a band diagram of conduction bands according to the embodiment;

FIG. 3 is a correlation diagram between lattice spacing and band gap energy according to the embodiment;

FIGS. 4A to 4C are views of lattice coupling between nitride semiconductor layers of the embodiment;

FIG. 5 is a graph showing a characteristic of a nitride semiconductor layer of the embodiment;

FIG. 6 is a cross-sectional view of a high frequency device according to a variation of the embodiment; and

FIG. 7 is a correlation diagram between lattice spacing and band gap energy according to the variation of the embodiment.

### DETAILED DESCRIPTION

According to one embodiment, a high frequency device includes a first nitride semiconductor layer, a second nitride semiconductor layer provided on the first nitride semiconductor layer, and a third nitride semiconductor layer provided on the second nitride semiconductor layer. The second nitride semiconductor layer contains an indium element (In), and has a layer thickness in a range of not less than 0.26 nanometers (nm) and not more than 100 nm.

Hereinafter, a high frequency device according to an embodiment will be described with reference to the drawings.

### Embodiment

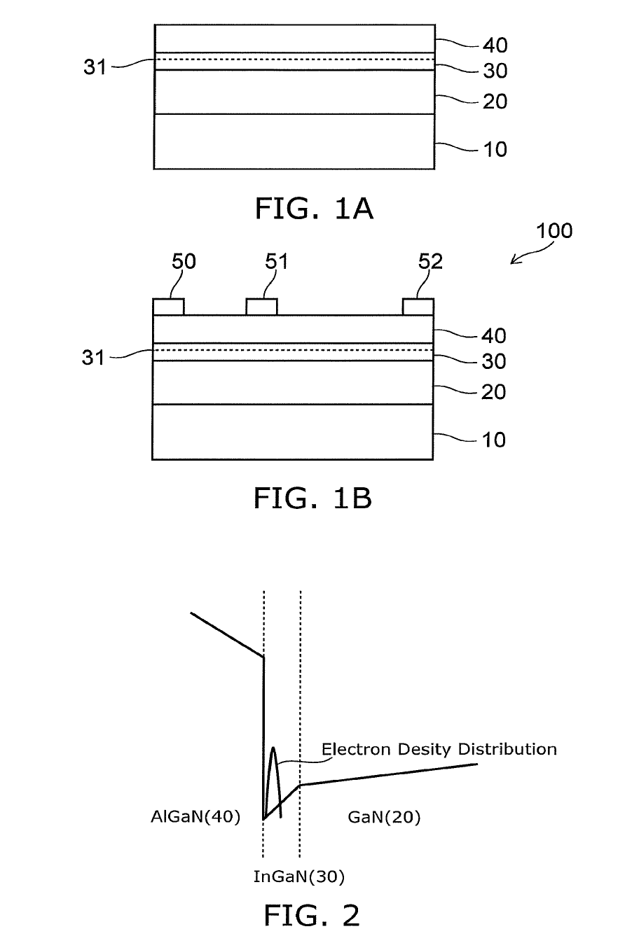

FIGS. 1A and 1B are cross-sectional views of a high frequency device 100 according to an embodiment. FIG. 1A is a cross-sectional view showing a structure of nitride semiconductor layers stacked on a substrate 10 according to the embodiment. FIG. 1B is a cross-sectional view of the high frequency device 100 in which electrodes are provided on the nitride semiconductor layers.

In the embodiment, a gallium nitride layer 20 (GaN layer, a first nitride semiconductor layer) is formed on the substrate 10. An indium gallium nitride layer 30 (InGaN layer, a second nitride semiconductor layer) is formed as a channel layer on the gallium nitride layer 20. Further, an aluminum gallium nitride layer 40 (AlGaN layer, a third nitride semiconductor layer) is formed on the indium gallium nitride layer 30.

The substrate 10 includes a material such as silicon (Si), silicon carbide (SiC), sapphire (α-Al₂O₃), gallium nitride (GaN), zinc oxide (ZnO), diamond, and the like. Note that, in the embodiment, the material of the substrate 10 is not limited thereto.

A source electrode 50, a gate electrode 51, and a drain electrode 52 are provided on the aluminum gallium nitride layer 40. The source electrode 50, the gate electrode 51, and the drain electrode 52 are provided to be spaced apart from each other. The source electrode 50 and the drain electrode 52 are provided so as to sandwich the gate electrode 51 therebetween.

A protective layer may be provided on the aluminum gallium nitride layer 40, the source electrode 50, the gate electrode 51 and the drain electrode 52. One example of the protective layer is a silicon nitride (SiN) layer or the like.

The gallium nitride layer 20, the indium gallium nitride layer 30, and the aluminum gallium nitride layer 40 are nitride semiconductor layers. In the embodiment, these layers are III-V semiconductor layers in which a group III element such as aluminum (Al), gallium (Ga), indium (In) and the like is combined with a group V element of nitrogen (N).

FIG. 2 is a band diagram of conduction bands according to the embodiment. The Indium gallium nitride layer 30 and the aluminum gallium nitride layer 40 have band gaps different from each other. When the indium gallium nitride layer 30 and the aluminum gallium nitride layer 40 are bonded to one another, a quantum well of an energy level is formed in the vicinity of the bonding interface (i.e., a hetero interface), and electrons are accumulated in the quantum well with high density, thereby forming two-dimensional electron gas 31.

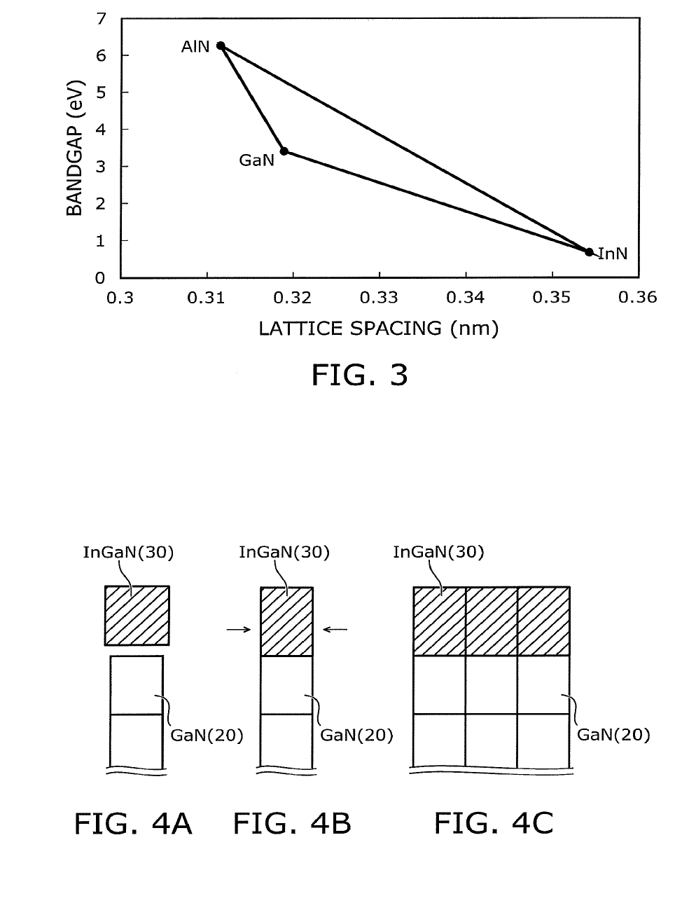

FIG. 3 is a correlation diagram between lattice spacing and band gap of nitride semiconductor. The band gap values of GaN, AlN and InN are plotted against the lattice spacing values thereof, and the plotted positions are connected with lines.

A line connecting the positions of GaN and AlN represents a characteristic of compound represented by Al_{y}Ga_{1-y}N, wherein “y” is the composition ratio of aluminum element (Al), and 0≤y≤1. That is, when a composition ratio of aluminum element (Al) is increased and a composition ratio of gallium element (Ga) is decreased, the compound approaches AlN, and the band gap thereof increases.

A line connecting the positions of GaN and InN represents a characteristic of compound represented by InₓGa₁₋ₓN, wherein “x” is a composition ratio of indium element (In), and 0≤x≤1. That is, when a composition ratio of indium element (In) is increased and a composition ratio of gallium element (Ga) is decreased, the compound approaches InN, and the band gap thereof decreases.

Since a band gap of the indium gallium nitride layer 30 is smaller than a band gap of the gallium nitride layer 20, it is possible to make the quantum well deeper by sandwiching the indium gallium nitride layer 30 between the gallium nitride layer 20 and the aluminum gallium nitride layer 40, and to increase the electron density of the two-dimensional electron gas 31. Moreover, it is possible to achieve high speed and high frequency characteristics, since electrons have a small effective mass in the nitride semiconductor containing indium elements.

In the embodiment, the semiconductor device 100 includes the indium gallium nitride layer 30 having a layer thickness of not less than 0.26 nm and not more than 100 nm. The minimum unit which configures the indium gallium nitride layer 30 (e.g., a primitive lattice of the InGaN crystal) has a thickness of 0.26 nm.

FIGS. 4A to 4C is diagrams of lattice coupling between the nitride semiconductor layers according to the embodiment. FIG. 4A is a schematic diagram showing inter-lattice spacing of the gallium nitride layer 20 and the indium gallium nitride layer 30 respectively. One square grid represents a unit cell. Since the lattice spacing of the indium gallium nitride layer 30 is larger than the lattice spacing of the gallium nitride layer 20 as shown in FIG. 3, the relation thereof is obtained as shown in FIG. 4A. In the embodiment, the indium gallium nitride layer 30 has a thickness of not less than 0.26 nm and not more than 100 nm, which is thinner than the gallium nitride layer 20.

FIG. 4B is a diagram of lattice coupling when the indium gallium nitride layer 30 is stacked on the gallium nitride layer 20. FIG. 4C is a diagram of lattice coupling between the gallium nitride layer 20 and the indium gallium nitride layer 30, showing a laterally continuing case.

For example, the indium gallium nitride layer 30 is formed at the initial stage of crystal growth so that the lattice spacing thereof coincides with the lattice spacing of the gallium nitride layer 20 in a direction along the interface between the gallium nitride layer 20 and the indium gallium nitride layer 30. That is, the crystal structure of the indium gallium nitride layer 30 is deformed at the initial stage of the crystal growth. When the gallium nitride layer 20 is thickly formed, the deformation of the gallium nitride layer 20 is suppressed at this time. Thus, the lattice spacing of the gallium nitride layer 20 is substantially same as the lattice constant of gallium nitride.

When the thickness of the indium gallium nitride layer 30 increases and exceeds the elastic limit thereof (i.e., the critical thickness), the lattice relaxation takes place, and defects are generated in the crystal. Accordingly, it is preferable to make a layer thickness of the indium gallium nitride layer 30 thinner than the critical thickness thereof in order to improve the crystal quality of the indium gallium nitride layer 30, which is the channel layer of the high frequency device 100, and to enlarge the carrier mobility in the channel layer.

The critical thickness depends on a degree of lattice mismatching between the gallium nitride layer 20 and the indium gallium nitride layer 30. R. People and J. C. Bean, Appl. Phys. Lett. 47, 322 (1985) disclose a relationship between a critical thickness and a degree of lattice mismatching, which is incorporated herein as a reference. The critical thickness h_{c} is expressed, for example, by the following equation.

$${h}_{c} = \frac{1 - v}{1 + v} \frac{1}{16 π \sqrt{2}} \frac{{b}^{2}}{a} \frac{1}{{f}^{2}} ln \frac{{h}_{c}}{b}$$

Here, “b” is a Burgers vector of defect; “a” is a lattice constant of gallium nitride; “v” is a Poisson's ratio; and “f” is a degree of lattice mismatching (e.g. Δa/a).

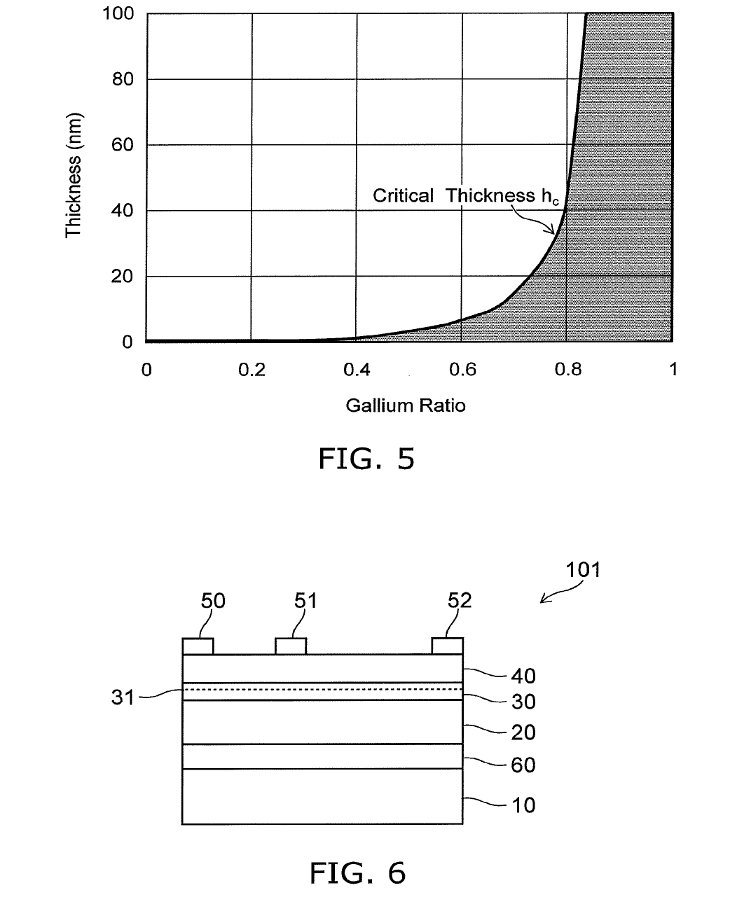

FIG. 5 is a graph showing a relationship of the critical thickness hₑ of the indium gallium nitride layer 30 and the gallium composition ratio thereof. The horizontal axis represents the gallium composition ratio, and the vertical axis represents the thickness of the indium gallium nitride layer 30. In an area shown in the drawing by shadowing where the thickness is thinner than the critical thickness h_{c}, no lattice relaxation takes place in the indium gallium nitride layer 30. That is, the indium gallium nitride layer 30 is preferably formed with a thickness in the shadowed area.

Also, the aluminum gallium nitride layer 40 is stacked on the indium gallium nitride layer 30 preferably in the same manner so that the lattice spacing of the aluminum gallium nitride layer 40 coincides with the lattice spacing of the gallium nitride layer 20, and the thickness of the aluminum gallium nitride layer 40 does not exceed the critical thickness thereof. Thereby, it is possible to form the high frequency device using high quality crystal in which trap levels or the like are suppressed.

Hereinafter, a manufacturing method of the semiconductor device 100 according to the embodiment will be described. In the semiconductor device 100, GaN crystal is grown by Metal Organic Chemical Vapor Deposition (MOCVD) or the like, and the gallium nitride layer 20 is stacked on the substrate 10. In the MOCVD method, organic metal and carrier gas are supplied on the substrate 10, and epitaxial growth is performed by a chemical reaction induced in gas phase over the heated substrate.

After the gallium nitride layer 20 is stacked on the substrate 10, organic metal sources such as trimethylindium (TMI), trimethylgallium (TMG), triethylgallium (TEG), triethylindium (TEI) and ammonia gas are supplied with carrier gas (e.g., nitrogen or hydrogen), and the indium gallium nitride layer 30 is stacked on the gallium nitride layer 20 by causing the reaction thereof.

After the indium gallium nitride layer 30 is stacked on the gallium nitride layer 20, trimethylgallium, triethylgallium, trimethylaluminum (TMA), ammonia gas and a carrier gas are similarly supplied, and the aluminum gallium nitride layer 40 is stacked on the indium gallium nitride layer 30 by causing the reaction thereof.

Noted that these stacking methods by the MOCVD method are described as one example, and the embodiment is not limited to the MOCVD method.

After the aluminum gallium nitride layer 40 is stacked, the source electrode 50, the gate electrode 51, and the drain electrode 52 are formed on the aluminum gallium nitride layer 40.

As described above, the semiconductor device 100 according to the embodiment includes the gallium nitride layer 20, the indium gallium nitride layer 30, and the aluminum gallium nitride layer 40. The indium gallium nitride layer 30 has a layer thickness of not less than 0.26 nm and not more than 100 nm. The semiconductor device 100 includes two-dimensional electron gas with high mobility and high density, since the indium gallium nitride layer 30 is formed without the lattice relaxation.

### First Variation of Embodiment

FIG. 6 shows a variation of the embodiment. In this example, the buffer layer 60 is stacked between the substrate 10 and the gallium nitride layer 20. The buffer layer 60 is inserted for improving crystalline quality of the gallium nitride layer 20, since defects are generated in the crystal structure of the gallium nitride layer 20 due to a difference in crystal structures of the substrate 10 and the gallium nitride layer 20, and may affect the stacking process of the indium gallium nitride layer 30. The buffer layer 60 is, for example, an indium aluminum gallium nitride layer expressed by a compositional formula of InₐAl_{b}Ga_{1-a-b}N (1≤a≤0, 1≤b≤0).

### Second Variation of Embodiment

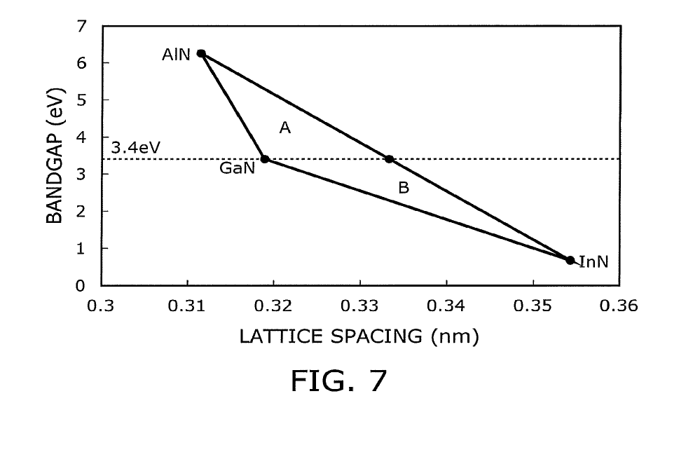

FIG. 7 is a correlation diagram between lattice spacing and band gap energy according to this example. The broken line in FIG. 7 represents the band gap value of gallium nitride (i.e., about 3.4 eV). In the triangle connecting the positions of AlN, GaN, and InN shown in the drawing, an A-area is defined above the broken line, and a B-area is defined below the broken line. That is, a band gap value in the A-region is larger than the band gap value of gallium nitride, and a band gap value in the B-region is smaller than the band gap value of gallium nitride.

In the second variation, the second nitride semiconductor layer may be formed of a material in the B-region, which has a band gap smaller than that of gallium nitride, in place of the indium gallium nitride layer 30. That is, the second nitride semiconductor layer may be one of an indium nitride (InN) layer, an indium aluminum gallium nitride (InAlGaN) layer, and an indium aluminum nitride (InAlN) layer, which has a band gap value smaller than that of gallium nitride (GaN).

Moreover, in the second variation, the third nitride semiconductor layer may be formed of a material in the A-region, which has a band gap larger than that of gallium nitride, in place of the aluminum gallium nitride layer 40. That is, the third nitride semiconductor layer may be one of an aluminum nitride (AlN) layer, an indium aluminum gallium nitride (InAlGaN) layer and an indium aluminum nitride (InAlN) layer, which has a band gap value larger than that of gallium nitride (GaN).

Also in the second variation, the buffer layer 60 may be provided in the same manner as in the first variation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A high frequency device comprising:
a first nitride semiconductor layer;
a second nitride semiconductor layer provided on the first nitride semiconductor layer, the second nitride semiconductor layer including indium atoms and having a layer thickness in a range of not less than 0.26 nanometers and not more than 100 nanometers; and
a third nitride semiconductor layer provided on the second nitride semiconductor layer and including aluminum atoms.

2. The device according to claim 1, wherein the second nitride semiconductor layer is provided without lattice relaxation.

3. The device according to claim 1, wherein the second nitride semiconductor layer has the layer thickness equal to or less than a critical thickness of the second nitride semiconductor layer.

4. The device according to claim 1, wherein the second nitride semiconductor layer has the layer thickness larger than a minimum unit of a material constituting the second nitride semiconductor layer and smaller than a critical thickness of the second nitride semiconductor layer.

5. The device according to claim 1, wherein the second nitride semiconductor layer has lattice spacing substantially same as lattice spacing of the first nitride semiconductor layer in a direction along an interface between the first nitride semiconductor layer and the second nitride semiconductor layer.

6. The device according to claim 5, wherein the third nitride semiconductor layer has lattice spacing substantially same as the lattice spacing of the first nitride semiconductor layer in a direction along an interface between the second nitride semiconductor layer and the third nitride semiconductor layer.

7. The device according to claim 1, wherein the second nitride semiconductor layer has the layer thickness thinner than a layer thickness of the first nitride semiconductor layer.

8. The device according to claim 1, wherein
the second nitride semiconductor layer has a band gap smaller than a band gap of the first nitride semiconductor layer, and has the band gap smaller than a band gap of the third nitride semiconductor layer.

9. The device according to claim 8, wherein
the first nitride semiconductor layer includes gallium nitride,
the second nitride semiconductor layer includes one of indium gallium nitride, indium nitride, indium aluminum gallium nitride and indium aluminum nitride, and
the third nitride semiconductor layer includes one of aluminum gallium nitride, aluminum nitride, indium aluminum gallium nitride and indium aluminum nitride.

10. The device according to claim 1, wherein
the first nitride semiconductor layer is a gallium nitride layer,
the second nitride semiconductor layer is one of an indium gallium nitride layer, an indium nitride layer, a first indium aluminum gallium nitride layer and a first indium aluminum nitride layer, the first indium aluminum gallium nitride layer and the first indium aluminum nitride layer having a band gap value smaller than the band gap value of gallium nitride, and
The third nitride semiconductor layer is one of an aluminum gallium nitride layer, an aluminum nitride layer, a second indium aluminum nitride layer and a second indium aluminum nitride layer, the second indium aluminum gallium nitride layer and the second indium aluminum nitride layer having a band gap value larger than the band gap value of gallium nitride.

11. The device according to claim 1, further comprising:
a substrate approximate to the first nitride semiconductor layer,
the first nitride semiconductor layer being positioned between the substrate and the third nitride semiconductor layer, and
the second nitride semiconductor layer being positioned between the first nitride semiconductor layer and the third nitride semiconductor layer.

12. The device according to claim 11, wherein the substrate includes one of silicon (Si), silicon carbide (SiC), aluminum oxide (α-Al₂O₃), gallium nitride (GaN), zinc oxide (ZnO) and diamond.

13. The device according to claim 11, further comprising:
a buffer layer provided between the substrate and the first nitride semiconductor layer, and including indium aluminum gallium nitride.

14. A high frequency device comprising:
a first semiconductor layer including a first nitride semiconductor;
a second semiconductor layer provided on the first semiconductor layer, and including a second nitride semiconductor containing indium atoms;
a third semiconductor layer provided on the second semiconductor layer, and including a third nitride semiconductor containing aluminum atoms;
the second semiconductor layer having a layer thickness larger than a minimum unit of the second nitride semiconductor, and smaller than a critical thickness of the second semiconductor layer.

15. The device according to claim 14, wherein the second semiconductor layer having the layer thickness in a range of not less than 0.26 nanometers and not more than 100 nanometers.

16. The device according to claim 14, wherein
the second semiconductor layer has first lattice spacing in a direction along an interface between the first semiconductor layer and the second semiconductor layer, the first lattice spacing being substantially same as a lattice constant of the first nitride semiconductor.

17. The device according to claim 16, wherein
the third semiconductor layer has second lattice spacing in a direction along an interface between the second semiconductor layer and the third semiconductor layer, the second lattice spacing being substantially same as the lattice constant of the first nitride semiconductor.

18. The device according to claim 14, wherein
the second nitride semiconductor has a band gap value smaller than a band gap value of the first nitride semiconductor and a band gap value of the third nitride semiconductor.
